(19) United States
(12) Patent Application Publication
(10) Pub. No.: US 2010/0235713 A1
(43) Pub. Date: Sep. 16, 2010

(54) NON-VOLATILE MEMORY GENERATING READ RECLAIM SIGNAL AND MEMORY SYSTEM

(75) Inventors: Chul-ho LEE, Suwon-si (KR); Young-joon CHOI, Seongnam-si (KR); Jong-hwa KIM, Seoul (KR)

Correspondence Address: VOLENTINE & WHITT PLLC, ONE FREEDOM SQUARE, 11951 FREEDOM DRIVE SUITE 1260, RESTON, VA, 20190, US

(73) Assignee: Samsung Electronics Co., Ltd., Suwon-si (KR)

(21) Appl. No.: 12/618,923

(22) Filed: Nov. 16, 2009

(30) Foreign Application Priority Data
Mar. 12, 2009 (KR) 10-2009-0021241

(51) Int. Cl. H03M 13/05; G06F 11/10

(52) U.S. Cl. 714/763; 714/E11.032

(57) ABSTRACT

A non-volatile memory device includes a memory cell array including memory blocks, an ECC circuit receiving read data from the memory cell array and detecting error bits, wherein the ECC circuit is capable of detecting and correcting a maximum number of error bits, a counter counting detected error bits and generating an error-possible data indication when the counted error bits exceed a minimum error threshold, wherein the minimum error threshold is less than the maximum number of error bits, and a read reclaim indicator receiving the error-possible data indication and generating read reclaim indication for the memory block storing the read data.

### CROSS-REFERENCE TO RELATED APPLICATIONS

This application claims the benefit of Korean Patent Application No. 10-2009-0021241 filed on Mar. 12, 2009, the subject matter of which is hereby incorporated by reference.

### BACKGROUND

The inventive concept relates to semiconductor memory devices, and more particularly, to a flash memory device generating a read reclaim signal and a memory system incorporating same.

Early flash memory devices included memory cell arrays of single-level memory cells capable of storing one bit of data (i.e., “0” or “1”) per memory cell. However, as the demand for memory rises within constituent host devices, contemporary flash memory devices have increasingly incorporated multi-level flash memory cells capable of storing two or more bits of data per memory cell. Taking 2-bit multi-level flash memory cells as an example, four (4) threshold voltages (Vth) are used to define four memory cell states corresponding to data values of “01”, “00”, “10”, and “11”.

A block of flash memory cells may be repeatedly read, but each memory cell may be programmed or erased only a predetermined number of “cycles” before its performance characteristics begin to deteriorate. Thus, as flash memory cells within a defined flash memory block deteriorate over time, the overall data storage capacity of the block is reduced. In other words, the number of program or erase cycles possible for each block of the flash memory block is limited. For example, a typical conventional multi-level memory cell block may be erased about 10,000 times before being regarded as “exhausted” (i.e., not usable anymore). As the data storage capacity of a flash memory device is reduced over time, the usefulness of the flash memory device to an incorporating host device is reduced.

Thus, the degree of exhaustion for a block (i.e., a physical arrangement of memory cells within a flash memory device) will increase with the number of programming operations directed to the block. This is particularly important when one considers that many programming operations involve (or possibly involve) a number of programming loops being applied to identified memory cells in a block. That is, when memory cells in a block need not be accessed (e.g., reprogrammed) a substantial number of times during a particular operation, the number of program and erase cycles that may permissibly be applied to the memory cells is increased.

One approach to controlling the level of memory cell wear and exhaustion uses a logic block address (LBA). A LBA is defined by a host device incorporating the flash memory device and may be used to control access to various blocks and memory cells within the flash memory device. When the host device repeatedly programs data to or erases data in a block associated with an LBA, memory cells located at a physical address corresponding to the logical address may become worn.

Uneven wear of respective blocks can dramatically limit the overall utility of flash memory. That is, some blocks may become exhausted well before other blocks, but the presence of an exhausted block reduces the data storage capacity of the flash memory device and performance of a constituent flash memory system. Besides performance deterioration caused by exhausted or worn blocks, insufficiently worn blocks (i.e., memory block with dramatically less use) are also capable of degrading the performance of a flash memory device. More typically, when critical or frequently accessed data is statically stored in a particular block, the risk of exhaustion to this block increases and the critical data may ultimately be lost.

To increase the probability that all blocks will experience uniform wear, a so-called “wear leveling operation” or a “read reclaim” operation has typically been performed. The read reclaim operation changes the access relationship between a logical address and multiple physical addresses. By changing the physical location of memory cells accessed by a particular logical address (i.e., a LBA), wear may be spread across a range of blocks or memory cells within a block. Careful wear leveling control by a read reclaim operation can thus extend the life of the flash memory device.

One symptom of memory cell wear is the spreading of threshold voltages. For example, assuming the particular threshold voltage distribution and corresponding data state assignments shown in Figure (FIG. 1, increased memory cell wear tends to cause a spreading and eventual overlap between adjacent threshold voltages. Unfortunately, as the physical size of multi-level memory cells is reduced with increasing integration, the error rate for read data retrieved from multi-level flash memory devices increases. Accordingly, in order to maintain acceptable data reliability for a memory system incorporating multi-level flash memory device(s), many contemporary host devices use some form of error detection and correction (ECC).

Since this read data error rate varies between multi-level flash memories, a high performance ECC capability—normally involving many sophisticated, high speed calculations—is required in order to increase reliability of the memory system. Often this capability can only be provided by incorporating some degree of ECC within the memory device, since the error correction capabilities of certain host devices may be limited. This result drives up the cost of the memory system. Such cost-premium, flash memory devices are not commercially compatible with memory systems used in certain low-priced, portable recording/reproducing devices, such as a memory stick (MS), a multimedia card (MMC), an XD picture (XD), a secure digital (SD) card, a compact flash (CF), a smart media card (SMC), a micro-drive (MD), etc.

### SUMMARY

The inventive concept provides non-volatile memory devices capable of performing error detection and correction (ECC) as well as performing read reclaim operations. The inventive concept also provides memory systems incorporating such non-volatile memory devices.

According to an aspect of the inventive concept, there is provided a non-volatile memory device comprising; a memory cell array of nonvolatile memory cells arranged in a plurality of memory blocks, an error detection and correction (ECC) circuit configured to receive read data from the memory cell array and detect a number of error bits in the read data, wherein the ECC circuit is capable of detecting and correcting a maximum number of error bits, a counter configured to count a number of detected error bits in the read data and generate an error-possible data indication when a number of counted error bits exceeds a minimum error threshold, wherein the minimum error threshold is less than the maximum number of error bits, and a read reclaim indicator configured to receive the error-possible data indication and generate read reclaim indication for one of the plurality of memory blocks storing the read data.

According to another aspect of the inventive concept, there is provided a system comprising; a host controlling operation of a nonvolatile memory device, wherein the nonvolatile memory device comprises, a memory cell array of nonvolatile memory cells arranged in a plurality of memory blocks, an error detection and correction (ECC) circuit configured to receive read data from the memory cell array and detect a number of error bits in the read data, wherein the ECC circuit is capable of detecting and correcting a maximum number of error bits, a counter configured to count a number of detected error bits in the read data and generate an error-possible data indication when a number of counted error bits exceeds a minimum error threshold, wherein the minimum error threshold is less than the maximum number of error bits, and a read reclaim indicator configured to receive the error-possible data indication and provide a read reclaim indication to the host for one of the plurality of memory blocks storing the read data.

### BRIEF DESCRIPTION OF THE DRAWINGS

Embodiments of the inventive concept will be described in the description that follows with reference to the accompanying drawings in which:

FIG. 1 is a graph showing an exemplary threshold voltage distribution for a conventional multi-level memory cell;

FIG. 2 is a block diagram of a flash memory system according to an embodiment of the inventive concept; and

FIG. 3 is a block diagram of a flash memory system according to another embodiment of the inventive concept.

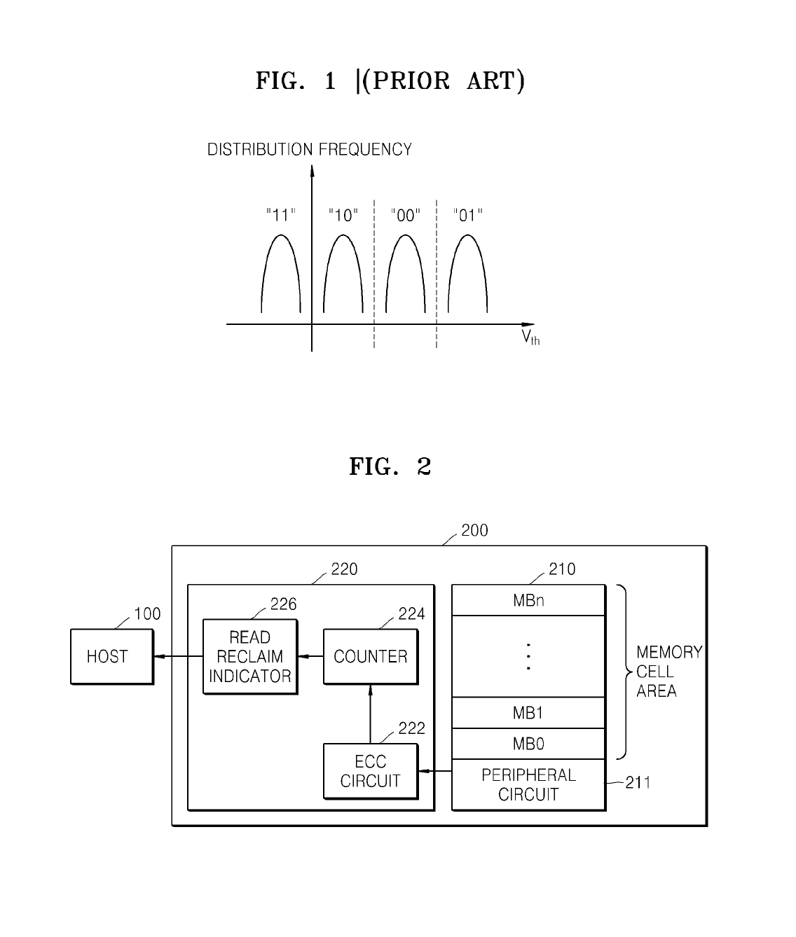

### DESCRIPTION OF EMBODIMENTS

Embodiments of the inventive concept will now be described with reference to the accompanying drawings. However, it should be noted that the inventive concept may be variously embodied and is not limited to only the illustrated embodiments. Rather, the illustrated embodiments are presented as teaching examples. Throughout the written description and drawings, like reference numbers and labels are used to indicate like or similar elements.

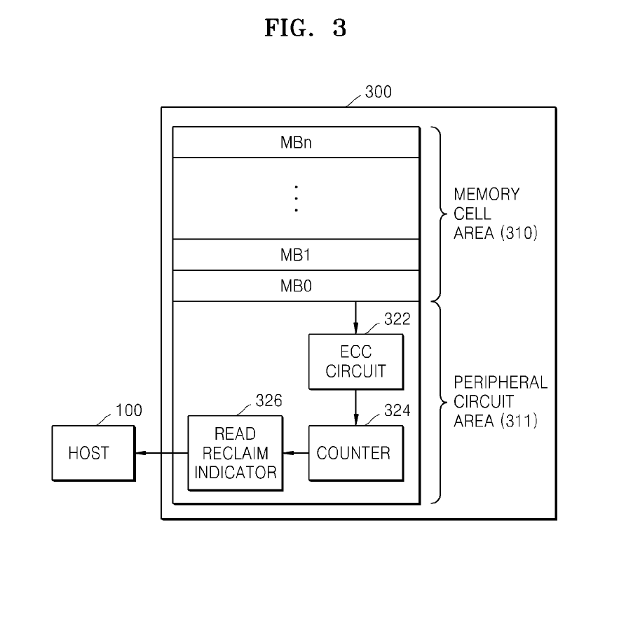

FIG. 2 is a block diagram of a flash memory system 200 according to an embodiment of the inventive concept. Referring to FIG. 2, the flash memory system 200 generally comprises a flash memory device 210 and a control unit 220.

As is conventionally understood, the flash memory device 210 includes an array of nonvolatile memory cells divided into a plurality of memory blocks (MB0 through MBn). A peripheral circuit 211 comprising a plurality of buffers, for example, is used to temporarily store “write data” to be programmed to the memory cell array and/or “read data” retrieved from the memory blocks MB0 through MBn. Each of the plurality of memory blocks MB0 through MBn is further assumed to be implemented by an arrangement of multi-level memory cells, each capable of storing at least 2 bits of data. In one example, each memory block has a size of 1 MB divided into 256 pages, where each page is 4 KB.

The control unit 220 includes an error detection and/or correction code (ECC) circuit 222, a counter 224, and a read reclaim indicator 226. The ECC circuit 222 generates an error correction code upon detecting an error in read data retrieved from the memory blocks MB0 through MBn. That is, in one example, the ECC circuit 222 will first obtain one (1) page of read data from the peripheral circuit 211 from each one of the plurality of memory blocks MB0 through MBn. Then, an error detection operation is performed by the ECC circuit 222 to identify ‘M” error bits, where M is a positive integer less than a defined maximum number of error bits “P” (e.g., up to 100 error bits). ECC circuit 222 now corrects the M error bits using one or more conventionally understood ECC algorithms and related procedures.

The counter 224 counts the number of error bits in one page of read data received by the ECC circuit 222. If the resulting counted number of error bits “N” is greater than a defined minimum error threshold, then the control unit 220 determines that the read data is “error-possible data”. For example, assuming a maximum detectable/correctable number of error bits is 100 and a minimum error threshold of 80, the counter 224 will generate an error-possible data indication if 80 or more error bits (i.e., an 80% of maximum error rate) are detected by EEC circuit 222. A page of read data producing a counted number of error bits N greater than the minimum error threshold but less than the maximum number of error bits P will thus be designated as error-possible data currently being stored in an error-possible memory block.

Per the foregoing discussion, the rate or error bit occurrence in any given memory block will change over time with use (i.e., wear), use conditions, and related factors such as threshold voltage spread, etc. Accordingly, value of the minimum error threshold producing an error possible data indication from counter 224 may be arbitrarily set in view of the foregoing.

The read reclaim indicator 226 generates a read reclaim indication that indicates to a host 100 that a particular memory block among the plurality of memory blocks MB0 through MBn currently stores a page of read data including a number of error bits exceeding the minimum error threshold and is therefore error-possible data. The read reclaim indication may also be used (i.e., at another value) to identify a page of read data including error bits exceeding the maximum number of error bits P capable or being corrected by the ECC circuit 222 (i.e., error-present data).

The host 100 may receive the read reclaim indication during an otherwise conventional wear leveling operation (or a read reclaim operation). Thus, when a physical address associated with a frequently used logical address experiences a high number of program/erase cycles, and the constituent memory block begins to wear and generate error bits, it is possible for the host to receive some indication of this condition before the read data deteriorates to the point where more than the maximum number of error bits P is included. Logical addresses related to a page of error-possible data may then be changed to avoid exhausting the page further. That is, prior indication of error-possible data may be used to better spread wear across a number of memory blocks during a wear leveling operation.

Accordingly, the flash memory system 200 uses read reclaim indication that is generated according to an error bit rate in consideration of the characteristics of a multi-level memory cell to change an error-possible memory cell block to another memory cell block before error bits are actually generated, thereby increasing the reliability of the flash memory system 200.

FIG. 3 is a block diagram of a flash memory system including a flash memory device 300 according to another embodiment of the inventive concept. Referring to FIG. 3, the flash memory device 300 omits the separate control unit 220 of the embodiment of FIG. 2 but directly incorporates an ECC circuit 322, a counter 324, and a read reclaim indicator 326 into a peripheral circuit area 311(e.g., an area including page buffers).

The operation of the ECC circuit 322, counter 324, and read reclaim indicator 326 are similar to the ECC circuit 222, counter 224, and read reclaim indicator 226 of control unit 220. The provision and layout of a peripheral circuit area within the flash memory device 300 in relation to memory cell area 310 may be generally accomplished using any number of conventionally understood techniques modified to allow the inclusion of ECC circuit 322, counter 324, and read reclaim indicator 326.

Thus, error detection and/or correction may be performed within the flash memory device 300 without separately providing a control unit. Thus, the flash memory device 300 is appropriate when the maximum number of error bits that the ECC circuit 322 is capable of detecting and correcting error is large. Accordingly, the error detection and correction processing of the flash memory device 300 can be performed at high speed. Also, when the ECC circuit 322 includes only an error detection function of data bit read from the memory cell blocks MB0 through MBn, the reliability of the flash memory device 300 can be increased and a chip size of the flash memory device 300 can also be reduced at the same time, thereby reducing the price of the flash memory device 300.

While the inventive concept has been particularly shown and described with reference to exemplary embodiments thereof, the exemplary embodiments should be considered in descriptive sense only and not for purposes of limitation. For example, the above-described embodiments are related to a multi-level cell that stores two bits of data; however, the inventive concept may also be applied to multi-level memory cells that store various bits of data such as three bits or four bits. Also, the type of the flash memory device which is used as a non-volatile memory and the capacity and configuration of the memory cell blocks may be in various combinations. Therefore, the scope of the inventive concept is not limited to only the detailed description of the inventive concept but by the appended claims.

What is claimed is:

1. A non-volatile memory device comprising:
a memory cell array of nonvolatile memory cells arranged in a plurality of memory blocks;
an error detection and correction (ECC) circuit configured to receive read data from the memory cell array and detect a number of error bits in the read data, wherein the ECC circuit is capable of detecting and correcting a maximum number of error bits;
a counter configured to count a number of detected error bits in the read data and generate an error-possible data indication when a number of counted error bits exceeds a minimum error threshold, wherein the minimum error threshold is less than the maximum number of error bits; and
a read reclaim indicator configured to receive the error-possible data indication and generate read reclaim indication for one of the plurality of memory blocks storing the read data.

2. The non-volatile memory device of claim 1, further comprising a peripheral circuit configured to obtain the read data from the memory cell array and provide the read data to the ECC circuit.

3. The non-volatile memory device of claim 1, wherein the ECC circuit, the counter and the read reclaim indicator are collectively implemented in a control unit separate from the memory cell array.

4. The non-volatile memory device of claim 1, wherein the read reclaim indicator is further configured to generate an error-present indication when the number of counted error bits exceeds the maximum number of error bits.

5. The non-volatile memory device of claim 1, wherein the nonvolatile memory cells are multi-level memory cells capable of storing at least two bits of data per memory cell.

6. The non-volatile memory device of claim 5, wherein the minimum error threshold within the counter may be set to a value in accordance with characteristics of the multi-level memory cells.

7. The non-volatile memory device of claim 1, wherein the read data is one page of data in one of the plurality of memory blocks.

8. A system comprising:
a host controlling operation of a nonvolatile memory device, wherein the nonvolatile memory device comprises:
a memory cell array of nonvolatile memory cells arranged in a plurality of memory blocks;
an error detection and correction (ECC) circuit configured to receive read data from the memory cell array and detect a number of error bits in the read data, wherein the ECC circuit is capable of detecting and correcting a maximum number of error bits;
a counter configured to count a number of detected error bits in the read data and generate an error-possible data indication when a number of counted error bits exceeds a minimum error threshold, wherein the minimum error threshold is less than the maximum number of error bits; and
a read reclaim indicator configured to receive the error-possible data indication and provide a read reclaim indication to the host for one of the plurality of memory blocks storing the read data.

9. The system of claim 8, wherein the read reclaim indication is provided to the host during a wear leveling operation controlled by the host.

10. The system of claim 9, wherein upon receiving the read reclaim indication the host reassigns a logical address previously assigned to the one of the plurality of memory blocks storing the read data.

11. The system of claim 8, wherein the nonvolatile memory device further comprises a peripheral circuit configured to obtain the read data from the memory cell array and provide the read data to the ECC circuit.

12. The system of claim 8, wherein the ECC circuit, the counter and the read reclaim indicator are collectively implemented in a control unit separate from the memory cell array within the nonvolatile memory device.

13. The system of claim 8, wherein the read reclaim indicator is further configured to generate an error-present indication to the host when the number of counted error bits exceeds the maximum number of error bits.

14. The system of claim 13, wherein upon receiving the error-present indication the host designates the one of the plurality of memory blocks storing the read data as an non-useable memory block.

15. The system of claim 13, wherein the nonvolatile memory cells are multi-level memory cells capable of storing at least two bits of data per memory cell.

16. The system of claim 15, wherein the minimum error threshold within the counter may be set to a value in accordance with characteristics of the multi-level memory cells.
